(19) United States
(12) Patent Application Publication
(10) Pub. No.: US 2006/0261831 A1
(43) Pub. Date: Nov. 23, 2006

(54) Integral probe and method of transmitting signal therethrough

(75) Inventors: Wan-Chuan Chou, Chang Hua County (TW); Wei-Fang Fan, Hsinchu County (TW); Jung-Tsan Liu, Taipei Hsien (TW)

Correspondence Address: BACON & THOMAS, PLLC, 625 SLATERS LANE, FOURTH FLOOR, ALEXANDRIA, VA, 22314, US

(73) Assignees: Wan-Chuan Chou, Chang Hua County (TW); Wei-Fang Fan, Hsinchu County (TW); Jung-Tsan Liu, Taipei Hsien (TW)

(21) Appl. No.: 11/133,374

(22) Filed: May 20, 2005

(51) Int. Cl. G01R 31/02

(52) U.S. Cl. 324/761

(57) ABSTRACT

Provided are integral probe and method of transmitting signal therethrough. The probe is formed of an elongate coil spring including an intermediate portion and two end portions either connected to a signal transmission starting terminal or a signal transmission ending terminal. The number of the coils of the spring in a predetermined portion thereof is larger than that of the remaining portions. A signal transmission method comprises compressing the spring and passing a signal through the spring. The invention can cause signal to pass quickly with decreased resistance and substantially no inductance.

### BACKGROUND OF THE INVENTION

1. Field of Invention

The present invention relates to probes and more particularly to an integral probe and a method of transmitting signal therethrough with improved characteristics.

2. Related Art

Probes are well-known devices for testing a printed circuit board (PCB), wafer, IC (integrated circuit) encapsulation, communication product, LCD (liquid crystal display), or the like. Probes are characterized by high conductivity and low resistance. Thus, many newly developed electronic devices (e.g., cellular phones) having probes as requisite components.

A conventional probe of low resistance (Prior Art I) is shown in FIG. 1. The probe comprises a sleeve 91 having a narrow top opening, a cup-shaped seat 94 fitted within a lower portion of the sleeve 91, a spring 93 in an internal space 911 of the sleeve 91, the spring 93 having a lower end anchored in the seat 94, and a projection 92 having a bottom cavity with an upper portion of the spring 93 anchored therein such that the projection 92 is urged upward by the spring 93 to project from the top opening of the sleeve 91 until an enlarged lower portion of the projection 92 is stopped by the narrow top opening of the sleeve 91. Moreover, the bottoms of the sleeve 91 and the seat 94 are secured together and the seat 94 is secured to an underlying member by soldering. The seat 94 is plated with tin and each of the sleeve 91, the spring 93, and the projection 92 is plated with precious metal. Prior Art I is configured to have low resistance. However, the number of its components is excessive. Also, its assembly is time consuming and may require high precision in the manufacturing process. Furthermore, its inductance is adversely large.

Another conventional probe for testing applications (Prior Art II) is shown in FIG. 2. The probe comprises a sleeve 81 having a narrow top opening and a blind bottom end, a spring 83 in an internal space of the sleeve 81, the spring 83 having a lower end rested on bottom of the sleeve 81, and a projection 82 having a bottom urged by the spring 83 such that the projection 82 is adapted to project from the top opening of the sleeve 81 until an enlarged lower portion of the projection 82 is stopped by the narrow top opening of the sleeve 81. Prior Art II has less components and less space as compared with Prior Art I. However, its manufacturing, assembly, and plating are still costly to implement. Moreover, resistance of the probe is relatively high when signal is transmitting. Further, its inductance is still adversely large.

As shown in FIG. 3, signal may travel through the spring 83 (or 93) for transmitting during test. In fact, signal travels through the helical length of the spring 83 as indicated by arrows. It is known that resistance is proportional to length of a signal transmission path. That is, the resistance is adversely large. Also, signal quality is poor due to large inductance. Thus, the need for improvement still exists.

### SUMMARY OF THE INVENTION

It is therefore an object of the present invention to, in a probe formed of an elongate coil spring including an intermediate portion and two end portions either connected to a signal transmission starting terminal or a signal transmission ending terminal, provide a signal transmission method comprising compressing the spring and passing a signal through the spring. By utilizing the method, signal can pass the compressed probe quickly with decreased resistance and substantially no inductance.

It is another object of the present invention to provide a probe formed of an elongate coil spring comprising an intermediate portion and two end portions either connected to a signal transmission starting terminal or a signal transmission ending terminal wherein the number of the coils of the spring in a predetermined portion thereof is larger than that of the remaining portions.

The above and other objects, features and advantages of the present invention will become apparent from the following detailed description taken with the accompanying drawings.

### BRIEF DESCRIPTION OF THE DRAWINGS

FIG. 1 is a sectional view of a conventional probe;

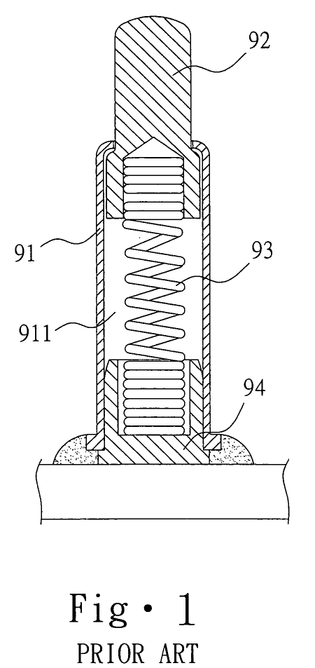

FIG. 2 is a sectional view of another conventional probe;

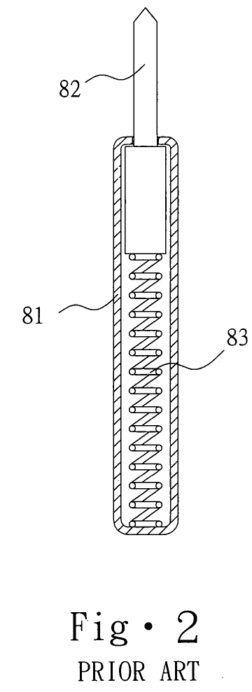

FIG. 3 is a sectional view of the spring shown in FIGS. 1 or 2 for illustrating signal transmission therethrough;

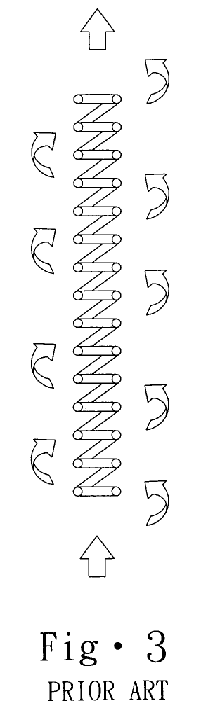

FIG. 4 is a side view of a first preferred embodiment of probe according to the invention;

FIG. 5 is a view similar to FIG. 4 where the probe is elastically compressed;

FIG. 6 is a side view of a second preferred embodiment of probe according to the invention;

FIG. 7 is a side view of a third preferred embodiment of probe according to the invention;

FIG. 8 is a side view schematically showing probes of the first preferred embodiment of the invention mounted in a device for wafer test;

FIG. 9 is a sectional view of the probe of the first preferred embodiment of the invention for illustrating signal transmission therethrough;

FIG. 10 is a side view of a fourth preferred embodiment of probe according to the invention;

FIG. 11 is a side view of a fifth preferred embodiment of probe according to the invention;

FIG. 12 is a view similar to FIG. 11 where the probe is elastically compressed;

FIG. 13 is a side view of a sixth preferred embodiment of probe according to the invention; and

FIG. 14 is a view similar to FIG. 13 where the probe is elastically compressed.

### DETAILED DESCRIPTION OF THE INVENTION

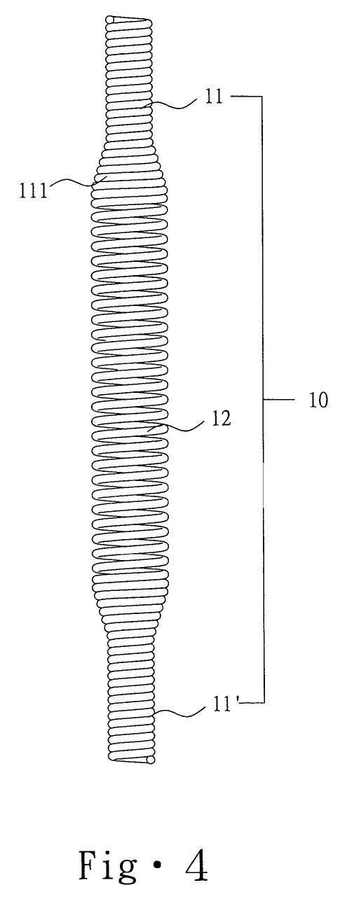

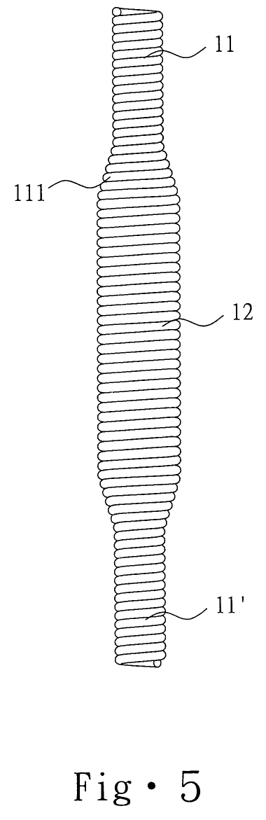

Referring to FIGS. 4, 5, and 8, there is shown an integral probe constructed in accordance with a first preferred embodiment of the invention. The probe is formed of elongate metal spring 10 comprising an enlarged intermediate portion 12, two end portions 11 and 11′, and two funnel-shaped connecting portions 111 either connected between the intermediate portion 12 and the end portion 11 (or 11′). The number of coils of the intermediate portion 12 is less than that of either end portion 11 or 11′. Also, the number of coils of the probe can be increased or decreased depending on applications.

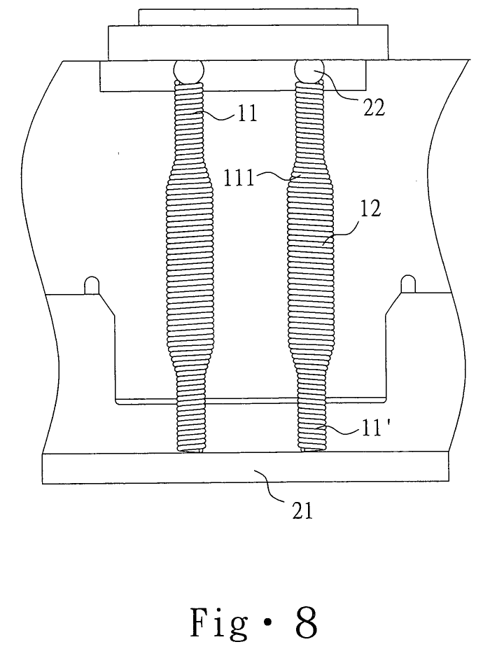

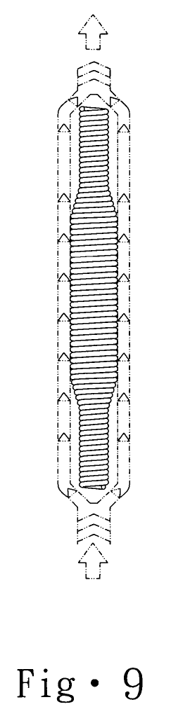

In an application as shown in FIG. 8, two probes each is interconnected a substrate 21 and a solder ball 22 on an IC board. Signal is transmitted from the substrate 21 to the solder ball 22 through either probe. Referring to FIG. 9, signal can pass the compressed probe quickly with decreased resistance and substantially no inductance as compared with prior art. Moreover, a buffering effect to the substrate 21 and the solder balls by the probes occurs due to elasticity of the probe. Such is particularly important for preventing properties of the solder balls 22 from degrading because test is always conducted in a high temperature environment.

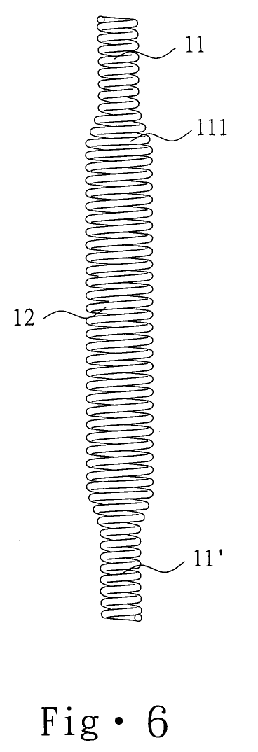

Referring to FIGS. 6, 7, and 10 to 14, second, third, fourth, fifth, and sixth preferred embodiments of probe according to the invention are shown. In FIG. 6 (second preferred embodiment), the probe comprises an enlarged intermediate portion 12, two end portions 11 and 11′, and two funnel-shaped connecting portions 111 either connected between the intermediate portion 12 and the end portion 11 (or 11′). The coils of the probe are formed uniformly.

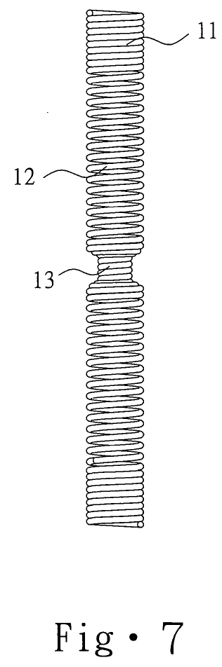

In FIG. 7 (third preferred embodiment), the probe comprises a narrow intermediate portion 13, two end portions 11, and two transitional portions 12 either connected between the intermediate portion 13 and the end portion 11. The number of coils of either transitional portion 12 is less than that of the intermediate portion 13 or that of either end portion 11.

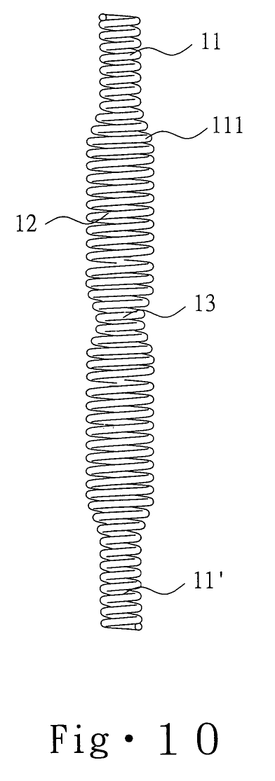

In FIG. 10 (fourth preferred embodiment), the probe comprises a narrow intermediate portion 13, two enlarged transitional portions 12, two narrow end portions 11 and 11′, and two funnel-shaped connecting portions 111 either connected between the intermediate portion 12 and the end portion 11 (or 11′). The coils of the probe are formed uniformly.

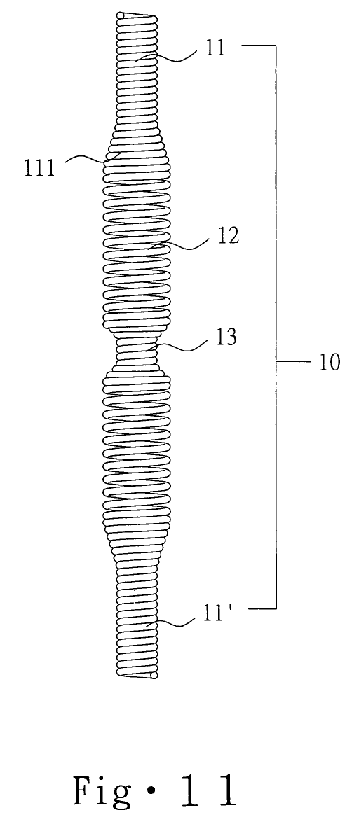

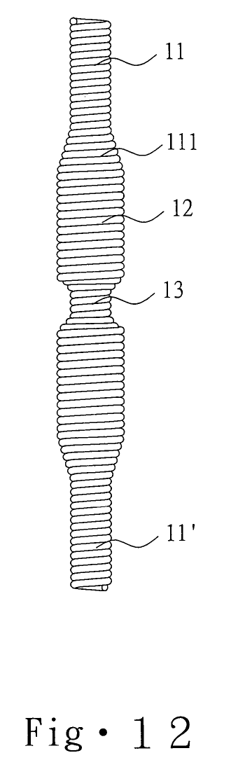

In FIG. 11 (fifth preferred embodiment), the probe comprises a narrow intermediate portion 13, two end portions 11 and 11′, two transitional portions 12 either connected between the intermediate portion 13 and a funnel-shaped connecting portions 111 of the end portion 11 (or 11′). The number of coils of either transitional portion 12 is less than that of each remaining component of the probe. As such, a uniform probe can be formed by compressing as shown in FIG. 12.

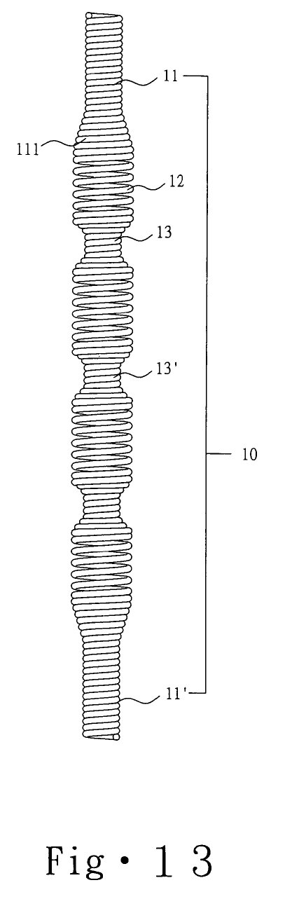

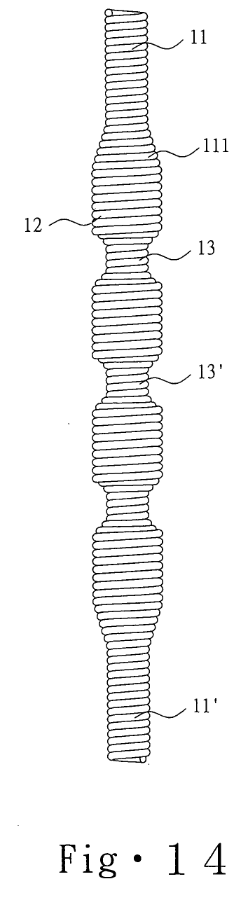

In FIG. 13 (sixth preferred embodiment), the probe comprises two end portions 11 and 11′ and a plurality of enlarged portions 12 in which each of first and last enlarged portions 12 having one end (or the other end) connected to a funnel-shaped connecting portions 111 of the end portion 11 (or 11′). Also, a narrow portion 13 is interconnected two adjacent enlarged portions 12. The number of coils of each enlarged portion 12 is less than that of each remaining component of the probe. As such, a uniform probe can be formed by compressing as shown in FIG. 14.

While the invention herein disclosed has been described by means of specific embodiments, numerous modifications and variations could be made thereto by those skilled in the art without departing from the scope and spirit of the invention set forth in the claims.

What is claimed is:

1. In a probe formed of an elongate coil spring including an intermediate portion and two end portions either connected to a signal transmission starting terminal or a signal transmission ending terminal, a signal transmission method comprising compressing the spring and passing a signal through the spring.

2. The method of claim 1, wherein the number of the coils of the spring in a predetermined portion thereof is larger than that of the remaining portions.

3. The method of claim 1, wherein the intermediate portion is enlarged and either end portion comprises a funnel-shaped connecting portion connected to the intermediate portion.

4. The method of claim 3, wherein the number of the coils of the spring in either end portion is larger than that of the intermediate portion.

5. The method of claim 1, wherein the intermediate portion comprises a plurality of first sections, and further comprising a plurality of narrow second sections each interconnected two adjacent sections.

6. The method of claim 5, wherein the number of the coils of the spring in one or more predetermined sections thereof is larger than that of the remaining sections.

7. A probe formed of an elongate coil spring comprising an intermediate portion and two end portions either connected to a signal transmission starting terminal or a signal transmission ending terminal wherein the number of the coils of the spring in a predetermined portion thereof is larger than that of the remaining portions.

8. The probe of claim 7, wherein the intermediate portion is enlarged and either end portion comprises a funnel-shaped connecting portion connected to the intermediate portion.

9. The probe of claim 8, wherein the number of the coils of the spring in either end portion is larger than that of the intermediate portion.

10. The probe of claim 7, wherein the intermediate portion comprises a plurality of first sections, and further comprising a plurality of narrow second sections each interconnected two adjacent sections.

11. The probe of claim 10, wherein the number of the coils of the spring in one or more predetermined sections thereof is larger than that of the remaining sections.
